(19) United States
(12) Patent Application Publication
(10) Pub. No.: US 2009/0181486 A1
(43) Pub. Date: Jul. 16, 2009

(54) METHOD FOR PRODUCING A TRANSISTOR-TYPE HYDROGEN SENSOR

(75) Inventors: Huey-Ing Chen, Tainan City (TW); Wen-Chau Llu, Tainan City (TW); Chin-Tien Lin, Tainan City (TW)

Correspondence Address: RABIN & Berdo, PC, 1101 14TH STREET, NW, SUITE 500, WASHINGTON, DC, 20005, US

(73) Assignee: NATIONAL CHENG KUNG UNIVERSITY, Tainan City (TW)

(21) Appl. No.: 12/351,111

(22) Filed: Jan. 9, 2009

(30) Foreign Application Priority Data
Jan. 11, 2008 (TW) 097101222

(51) Int. Cl. H01L 21/30

(52) U.S. Cl. 438/49; 257/E21.211

(57) ABSTRACT

A method for producing a transistor-type hydrogen sensor is invented. This method combines conventional semiconductor fabrication process with an electroless plating technique. The fabrication process comprises steps as follows: (a) preparing a semiconductor substrate, (b) forming a semiconductor-based material with an exposed surface on the substrate, (c) washing and then drying the semiconductor-based material, (d) separating the exposed surface of the semiconductor-based material, (e) depositing a gold-germanium alloy on the semiconductor-based material to form two Ohmic contacts, and (f) forming a Schottky contact gate metal having an affinity for hydrogen. The electroless plating technique deposits the Schottky contact gate metal, having an affinity for hydrogen, at a relatively low temperature and it thus can produce a transistor-type hydrogen sensor with excellent sensing performances.

### FIELD OF THE INVENTION

The present invention relates to the production of a transistor-type hydrogen sensor and, more particularly, to a method that uses an electroless plating technique in a semiconductor process to fabricate a transistor-type hydrogen sensor.

### BACKGROUND OF THE INVENTION

A sensor composed a catalytic metal film is conventionally used for hydrogen detection. When hydrogen molecules are adsorbed on the sensor, the hydrogen concentration can be determined by measuring changes in chemical or physical properties of the sensor. In general, hydrogen sensors are categorized into five types: (1) metal-oxide semiconductor, (2) electrochemical, (3) field-effect device, (4) catalytic, and (5) surface acoustic wave (SAW) types.

A conventional transistor-type hydrogen sensor is a field-effect one. The transistor-type hydrogen sensor mainly comprises a semiconductor substrate, a channel layer, a Schottky contact (a catalytic gate metal) and two Ohmic contacts ( terminals of drain and source). The interface between the gate metal and the Schottky contact layer has a dominant effect on electrical properties and sensing performances of the sensor.

Methods for the deposition of the Schottky contact metal include thermal evaporation, electron-gun (e-gun), sputtering, etc. The high-energy deposition of said methods often causes thermal damage on the semiconductor surface. Since the metal-semiconductor interface accumulates surface charge, it results in the pinning of the Schottky barrier height to a constant value. This phenomenon is called “Fermi-level pinning effect” which can deteriorate the electrical properties and sensing performances of the transistor.

### SUMMARY OF THE INVENTION

The main objective of the present invention is to provide a method for producing transistor-type hydrogen sensors with excellent sensing performances.

A method for producing a transistor-type hydrogen sensor in accordance with the present invention combines a semiconductor fabrication process with an electroless plating technique and comprises steps of (a) preparing a semiconductor substrate; (b) forming a semiconductor-based material with an exposed surface on the substrate; (c) washing and then drying the semiconductor-based material; (d) separating the exposed surface of the semiconductor-based material; (e) depositing a gold-germanium alloy on the semiconductor-based material to form two Ohmic contacts; and (f) forming the Schottky contact gate metal having an affinity for hydrogen by using electroless plating technique. As compared with the conventional deposition techniques, the electroless plating which is operated at a relatively low temperature can therefore reduce the Fermi-level pinning effect and lead to a superior sensing characteristics.

### BRIEF DESCRIPTION OF THE DRAWINGS

FIG. 1 is a perspective view of a hydrogen sensor produced by a method in accordance with the present invention.

FIG. 2a is a graph of charge density distribution of the hydrogen sensor shown in FIG. 1 in the absence of hydrogen.

FIG. 2a′ is the energy-band diagram of the hydrogen sensor shown in FIG. 1 in the absence of hydrogen.

FIG. 2b is a cross-sectional view of the hydrogen sensor shown in FIG. 1 with current flow in the absence of hydrogen.

FIG. 2c is a graph of charge density distribution of the hydrogen sensor shown in FIG. 1 in the presence of hydrogen.

FIG. 2c′ is the energy-band diagram of the hydrogen sensor shown in FIG. 1 in the presence of hydrogen.

FIG. 2d is a cross-sectional view of the hydrogen sensor shown in FIG. 1 with current flow in the presence of hydrogen.

FIG. 3 is a graph of current-voltage characteristics of the hydrogen sensor shown in FIG. 1 upon exposing to hydrogen gases with different hydrogen concentrations at 303 K.

FIG. 4 is a graph of current-voltage characteristics of the hydrogen sensor shown in FIG. 1 upon exposing to hydrogen gases with different hydrogen concentrations at 503K.

FIG. 5 is a graph of threshold voltage of the hydrogen sensor shown in FIG. 1 upon exposing to different hydrogen concentrations at different temperatures.

FIG. 6 is a graph of relative sensitivity of the hydrogen sensor shown in FIG. 1 upon exposing to hydrogen gases with different hydrogen concentrations at different temperatures.

FIG. 7 is a graph of transient responses of the hydrogen sensor shown in FIG. 1 at 503K.

### DESCRIPTION OF THE PREFERRED EMBODIMENT

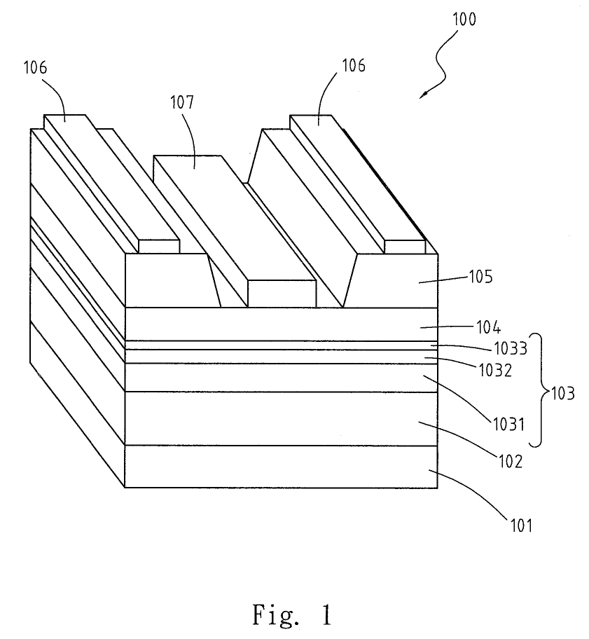

As shown in FIG. 1, a method for producing a transistor-type hydrogen sensor (100) in accordance with the present invention comprises steps of

(a) preparing a semiconductor substrate (101);

(b) forming a semiconductor-based material with an exposed surface on the substrate (101);

(c) washing and then drying the semiconductor-based material;

(d) separating the exposed surface of the semiconductor-based material;

(e) depositing a gold-germanium alloy on the semiconductor-based material to forming two Ohmic contacts (106); and

(f) forming a Schottky contact gate metal (107) having an affinity for hydrogen.

The substrate (101) in step (a) is made of semiconductor. Step (b) comprises forming a semiconductor-based material on the semiconductor substrate (101). The semiconductor-based material with an exposed surface comprises sequentially a semiconductor buffer layer (102), a semiconductor active layer (103), a Schottky contact layer (104) and a semiconductor cap layer (105), which can be formed using metal organic chemical vapor deposition (MOCVD) or molecular beam epitaxy (MBE).

Step (d) comprises separating the exposed surface of the semiconductor-based material, which can be performed by using a photo-lithography, a masking, and a wet-etching process, in order to form two separated semiconductor cap layers (105) and allow the following Schottky contact process.

Step (e) comprises depositing gold-germanium alloy layers on the separated semiconductor cap layers (105) to form two Ohmic contacts (106) by using a photo-lithography, a thermal evaporation, a lift-off and an optional annealing process. The annealing process is performed at a temperature ranging from 100 to 500° C. for the annealing time ranging from 1 to 600 sec.

Step (f) comprises forming a Schottky contact gate metal (107) having an affinity for hydrogen on the Schottky contact layer (104) with a wet-etching, a photo-lithography, a masking, an electroless plating, and a lift-off process and may further comprise a sensitization process and an activation process to increase the plating rate of the gate metal. Due to the low-temperature deposition by using electroless plating, the sensor device can result in the reduction of the Fermi level pinning effect, and thus it can improve electrical properties and enhance the hydrogen sensing performances of the transistor-type hydrogen sensor. The electroless plating of the gate metal is carried out at 20˜70° C. for 1˜120 minutes. The electroless bath comprises a metal precursor, a chelating agent, a reducing agent, a buffer, an optional stabilizer and an optional brightener with a pH value within 8˜12.

TABLE 1
Compositions of the electroless plating bath.

| Component | Concentration | |
|---|---|---|
| PdCl₂ | 4 | mM |
| Na₂EDTA | 15 | mM |
| NH₄OH (25%) | 25 | ml/L |
| N₂H₄ | 7 | ml/L |

The metal precursor is selected from a group comprising halides, nitrates, acetates and ammonium salts of a metal, and the concentration of the metal precursor is in the range of 1˜10 mM. For example, palladium chloride (PdCl₂) in Table 1 is provided as a palladium precursor which can be dissociated into palladium ions (Pd²⁺) in the plating bath.

The chelating agent is selected from a group comprising nitrates, ammonium salts, sulfates, halides, cyanates, acetates, carbamates, carbonates, phosphates, perborates, ethylenediamine, tetramethylethylenediamine and ethylenediamine tetraacetic acid disodium salt (Na₂EDTA). The concentration of the chelating agent is in the range of 4˜50 mM. For example, disodium ethylenediamine tetraacetic acid (Na₂EDTA) in Table 1 is served as the chelating agent.

The reducing agent is selected from a group comprising hydrazine, formaldehyde and reducing sugar. The concentration of the reducing agent is in the range of 50˜500 mM. For example, the hydrazine (N₂H₄) in Table 1 is used as a reducing agent.

The buffer is selected from a group comprising ammonium hydroxide, potassium hydroxide and sodium hydroxide. The ammonium hydroxide in Table 1 is used as a buffer.

The stabilizer is selected from a group comprising thiodiglycolic acid and thiourea.

The brightener is saccharin.

For the electroless plating of Pd gate, the Pd²⁺ ion is firstly chelated with EDTA to form a stable complex ion which can constantly release low concentration of free Pd²⁺ ions so that the reaction (1) can be accomplished free from bath decomposition. The reaction (1) is expressed as

2Pd²⁺+N₂H₄+4OH⁻→2Pd+N₂+4H₂O (1)

The sensitization process comprises immersing the semiconductor-based material in a sensitization solution for 5˜10 minutes, and then washing and drying the semiconductor-based material. The sensitization solution is acidic with containing stannous ions (Sn²⁺).

The activation process comprises immersing the semiconductor-based material in an acidic solution containing palladium for 5˜10 minutes, and then washing and drying the semiconductor-based material.

As shown in FIG. 1, a transistor-type hydrogen sensor (100) in accordance with the present invention is a transistor-type hydrogen sensor and comprises a semiconductor substrate (101), a semiconductor buffer layer (102), a semiconductor active layer (103), a Schottky contact layer (104), a semiconductor cap layer (105), two Ohmic contacts (106) and a Schottky contact gate metal (107).

The semiconductor substrate (101) comprises the semi-insulated gallium arsenide (GaAs).

An 8000 Å-thick-undoped GaAs buffer layer (102) is deposited on the semiconductor substrate (101).

The semiconductor active layer (103) is deposited on the semiconductor buffer layer (102) and comprises a semiconductor channel layer (1031), a semiconductor spacer layer (1032) and a planar-doped layer (1033). The semiconductor channel layer (1031) is a 130 Å-thick-undoped In_{0.18}Ga_{0.82}As layer and comprises L layer. A 40 Å-thick-undoped Al_{0.24}Ga_{0.76}As spacer layer (1032) is epitaxially deposited on the semiconductor channel layer (1031) and comprises M layer. The planar-doped layer (1033) doped with silicon (Si) has a concentration of 4.4×10¹² cm⁻³ and comprises N layer. The semiconductor active layer has (L+M+N)! arranging selections.

The Schottky contact layer (104) epitaxially deposited on the semiconductor active layer (103) can be a 500 Å-thick Al_{0.24}Ga_{0.76}As or In_{0.49}Ga_{0.51}P with a doping concentration of 3×10¹⁷ cm⁻³.

An 800 Å-thick semiconductor cap layer (105) is epitaxially deposited on the Schottky-contact layer (104).

Two Ohmic contacts (106) are deposited on a semiconductor cap layer (105) and are made of gold-germanium alloy.

The Schottky gate metal (107) is deposited on the Schottky contact layer (104), and is made of palladium (Pd).

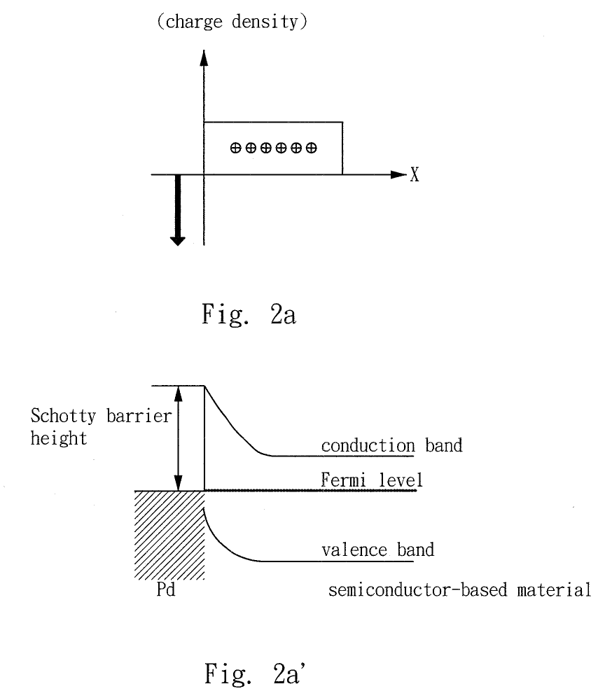

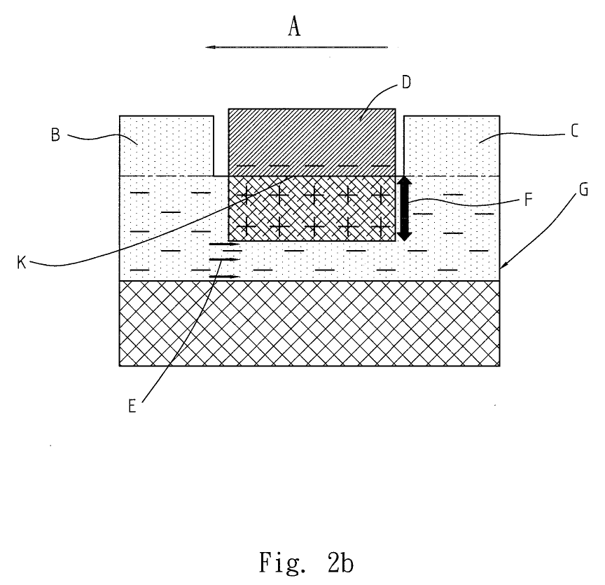

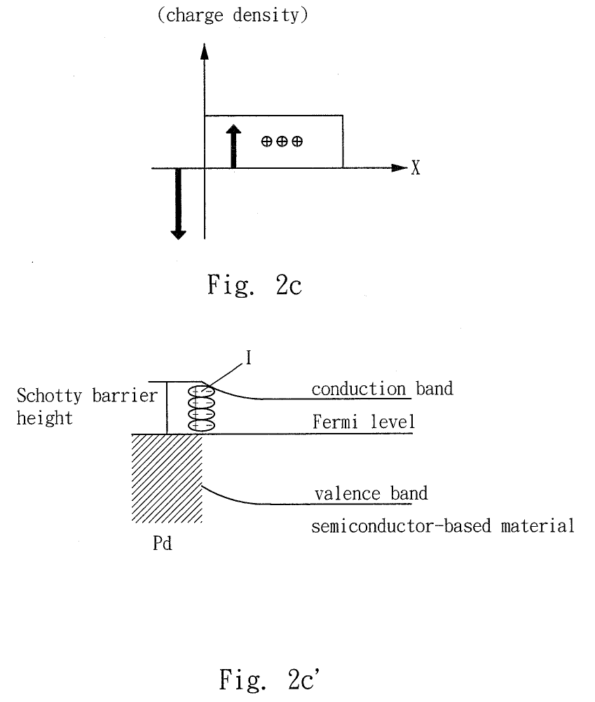

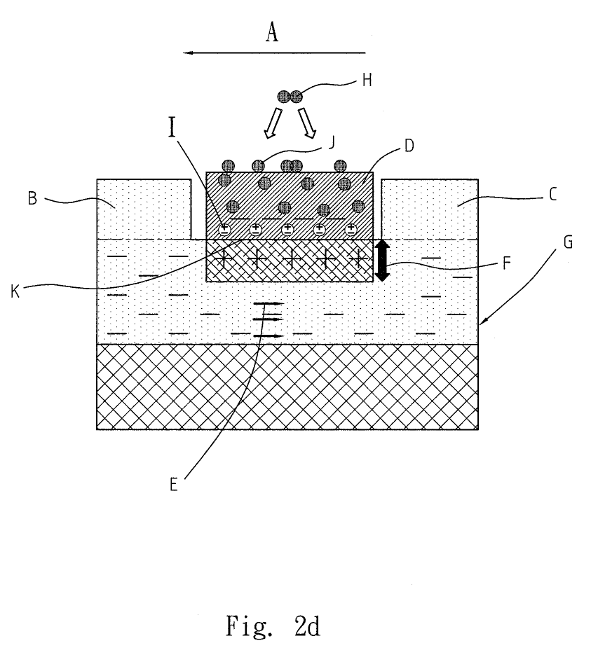

As indicated in FIGS. 2(a)˜2(d), under an applied gate voltage and in the absence of hydrogen, the electron current (E) (an opposite direction of electric current (A)) flows through the semiconductor-based material (G) from drain (C) to source (B).

When the sensor is exposed to hydrogen, the hydrogen molecule (H) is adsorbed on the Pd surface and simultaneously dissociated into hydrogen atoms (J). The hydrogen atoms (J) then diffuse to the interface between the Pd gate layer (D) and the semiconductor-based channel material (G). The hydrogen atoms adsorbed at the interface (K) is polarized by the built-in electric field to form a dipole layer (I). The electric field direction of the dipole layer (I) is opposite to that of depletion region (F). Thus, the net electric field is reduced, leading to the thinning of width of the depletion region (F) and the increase of drain (C)-source (B) output current. Basing on the above sensing principle, the hydrogen concentration can be determined from the change of the drain (C)-source (B) output current under an applied gate voltage.

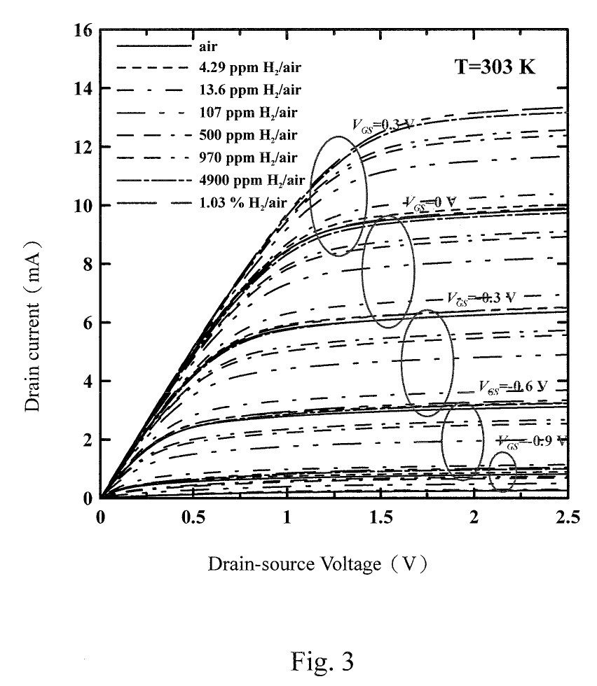

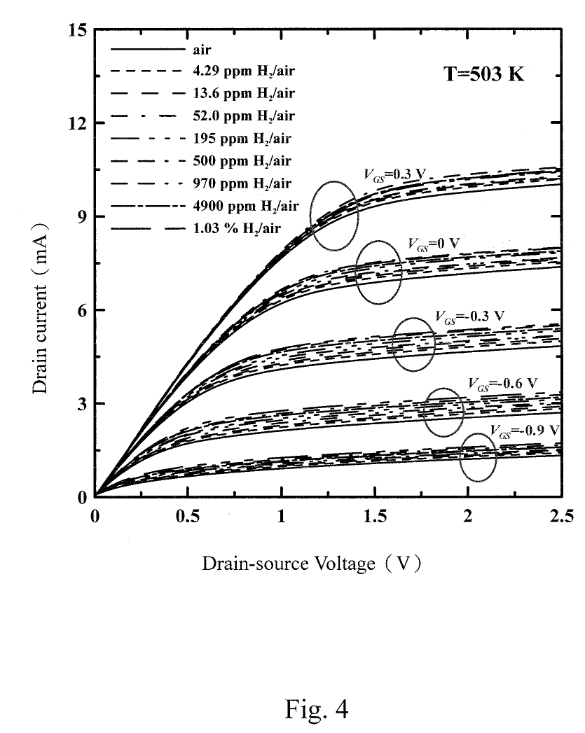

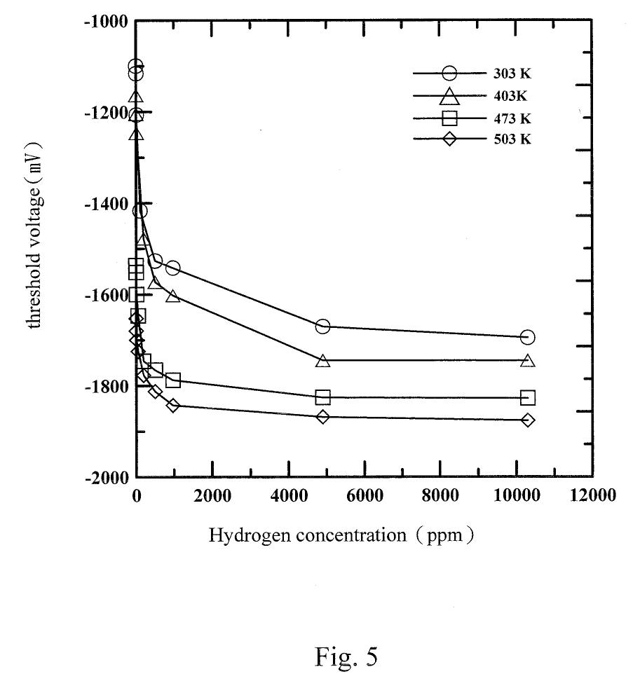

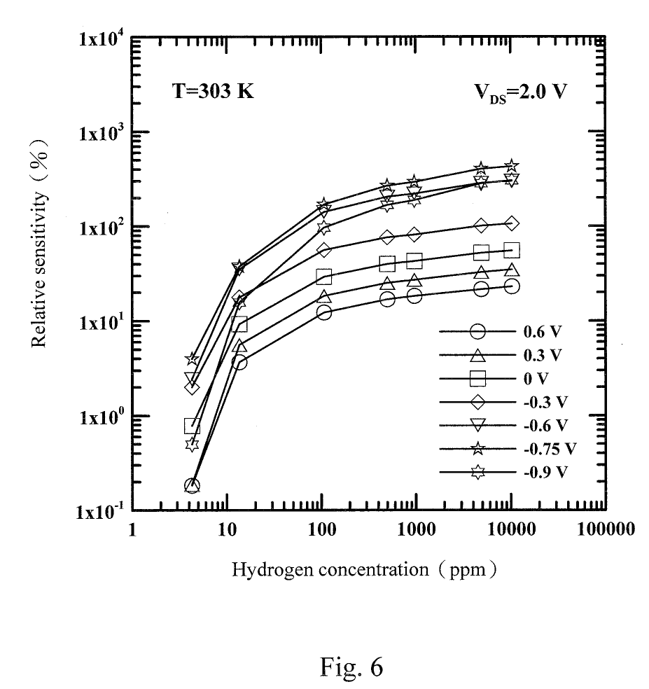

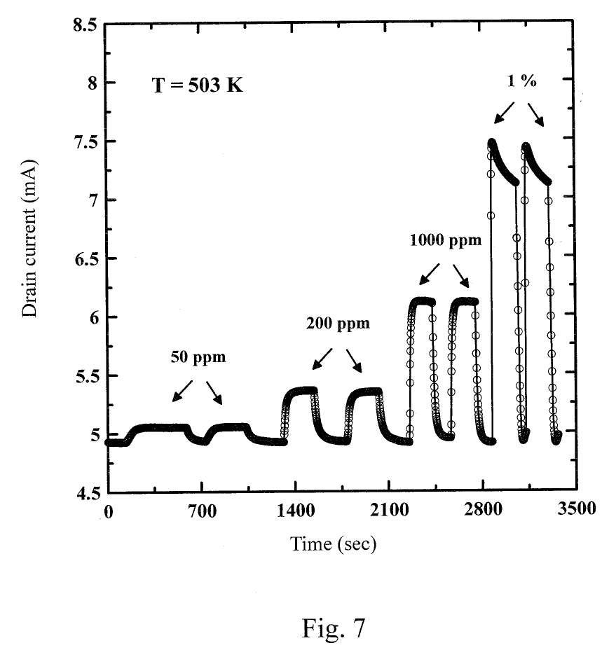

FIGS. 3-7 show the hydrogen sensing performances of the transistor-type hydrogen sensor produced by the method in accordance with the present invention. The lower detection limit is about 4.29 ppm H₂/Air and the detactable concentration allows up to 1.03% H₂/Air. This sensor exhibits quite excellent transistor characteristics at temperatures from 303 K to 503 K. When the transistor-type hydrogen sensor is operated at 303 K upon exposing to the gas with a concentration of 1.03% H₂/Air, the variation in threshold voltage is estimated as 600 meV. Moreover, the threshold voltage is decreased with increasing the hydrogen concentration, indicating that the threshold voltage can be modulated by the hydrogen concentration of gases. A maximum sensitivity, i.e., 428.33 % can be obtained at a gate voltage of −0.75 V and temperature of 303 K. In addition, this sensor demonstrates fairly good repeatability, reliability, and quick detection. It is worthy to note, the present method can be used for fabricating the transistor-type hydrogen sensor with a gate length even down to 1-μm level.

What is claimed is:

1. A method for produce a transistor-type hydrogen sensor comprising steps as following:
(a) preparing a semiconductor substrate;
(b) forming a semiconductor-based material with an exposed surface on the semiconductor substrate to form a semiconductor-based material having an exposed surface and being sequentially a buffer layer, an active layer, a Schottky contact layer and a semiconductor cap layer;
(c) washing and then drying the semiconductor-based material;
(d) separating the exposed surface of the semiconductor-based material;
(e) depositing a gold-germanium alloy on the semiconductor-based material to form two Ohmic contacts; and
(f) forming a Schottky contact gate metal having an affinity for hydrogen by using electroless plating technique.

2. The method as claimed in claim 1, wherein
the buffer layer, the semiconductor active layer, the Schottky contact layer and the cap layer are formed in step (b) by metal organic chemical vapor deposition (MOCVD) or molecular beam epitaxy (MBE).

3. The method as claimed in claim 1, wherein
the exposed surface of the semiconductor-based material in step (d) is separated by using a photo-lithography, a masking and a wet-etching process.

4. The method as claimed in claim 1, wherein
the gold-gallium alloy layer deposited on the cap layers in step (e) is performed by a photo-lithography, a masking, a thermal evaporation and a lift-off process.

5. The method as claimed in claim 4, wherein step (e) further comprises an annealing process.

6. The method as claimed in claim 5, wherein the process is performed at an annealing temperature of 100˜500° C. for an annealing time of 1˜600 sec.

7. The method as claimed in claim 1, wherein step (f) comprises a wet-etching, a photo-lithography, a masking, an electroless plating, and a lift-off process.

8. The method as claimed in claim 7, wherein step (f) further comprising a sensitization process before the electroless plating, comprises immersing the semiconductor-based material in a sensitization solution for 5˜10 min and then washing and drying the semiconductor-based material, and the sensitization solution being acidic with containing stannous ions (Sn²⁺).

9. The method as claimed in claim 7, wherein step (f) further comprising an activation process after the sensitization process, comprises immersing the semiconductor-based material in an acidic solution containing palladium ions for 5˜10 minutes, and then washing and drying the semiconductor-based material.

10. The method as claimed in claim 1, wherein the reaction of the electroless plating technique is performed at 20˜70° C. for 1˜120 minutes.

11. The method as claimed in claim 1, wherein the electroless plating technique in step (f) uses an alkaline electroless plating bath comprising a metal precursor, a chelating agent, a reducing agent and a buffer.

12. The method as claimed in claim 11, wherein the alkaline electroless plating bath in step (f) further comprises a stabilizer.

13. The method as claimed in claim 12, wherein the alkaline electroless plating bath in step (f) further comprises a brightener.

14. The method as claimed in claim 11, wherein the metal precursor being selected from a group comprising halides, nitrates, acetates and ammonium salts of a metal, and the concentration being between 1˜10 mM.

15. The method as claimed in claim 11, wherein the reducing agent being selected from a group comprising hydrazine, formaldehyde and reducing sugar, and the concentration being in the range of 50˜500 mM.

16. The method as claimed in claim 11, wherein the chelating agent being selected from a group comprising nitrates, ammonium salts, sulfates, halides, cyanates, acetates, carbamates, carbonates, phosphates, perborates, ethylenediamine, tetramethylethylenediamine and ethylenediamine tetraacetic acid disodium salt (Na₂EDTA), and the concentration being between 4˜50 mM.

17. The method as claimed in claim 11, wherein the alkaline electroless plating bath being between pH 8˜pH12.

18. The method as claimed in claim 11, wherein the buffer being selected from a group comprising ammonium hydroxide, potassium hydroxide and sodium hydroxide.

19. The method as claimed in claim 12, wherein the stabilizer being selected from a group comprising thiodiglycolic acid and thiourea.

20. The method as claimed in claim 13, wherein the brightener being saccharin.
